(19) United States
(12) Patent Application Publication
(10) Pub. No.: US 2026/0285649 A1
(43) Pub. Date: Sep. 24, 2026

(54) OVERHEAD TRANSPORT VEHICLE

(71) Applicant: Murata Machinery, Ltd., Kyoto-shi, Kyoto (JP)

(72) Inventor: Makoto KOBAYASHI, Kyoto-shi (JP)

(21) Appl. No.: 19/472,234

(22) PCT Filed: Mar. 21, 2024
(86) PCT No.: PCT/JP2024/010937

§ 371 Date: Oct. 3, 2025

(30) Foreign Application Priority Data
Apr. 26, 2023 (JP) 2023-072521

(51) Int. Cl. B66C 1/22; B66C 1/28; H10P 72/30

(52) U.S. Cl. CPC B66C 1/223; B66C 1/28; H10P 72/3214; H10P 72/3218; H10P 72/3221

(57) ABSTRACT

An overhead transport vehicle to transport a container while holding down a lid placed atop the container includes a holder to hold the container, and an elevation driver to raise and lower the holder. The holder includes a lid presser to press the lid placed atop the container from above by the weight of the container when the container is held on the holder.

### BACKGROUND OF THE INVENTION

### 1. Field of the Invention

The present invention relates to overhead transport vehicles.

### 2. Description of the Related Art

Overhead transport vehicles that transport containers along a track arranged on a ceiling or similar structure are known (for example, see Japanese Unexamined Patent Application, First Publication No. 2018-125411). The container disclosed in Japanese Unexamined Patent Application, First Publication No. 2018-125411 accommodates wafers, reticles, and similar items used in the manufacturing of semiconductor devices.

### SUMMARY OF THE INVENTION

In some cases, an overhead transport vehicle transports a container filled with liquid instead of one containing wafers or reticles. A lid is provided atop such a container. In such a case, the overhead transport vehicle needs to hold down the lid of the container to prevent the liquid in the container from spilling out when transporting the container.

Consequently, one might consider adding a driving motor to the overhead transport vehicle specifically for holding down the lid. However, such an addition necessitates careful design considerations regarding weight and power consumption, which could lead to increased complexity in the overall configuration.

Example embodiments of the present invention provide overhead transport vehicles each with a simple configuration to transport a container while holding down the lid of the container.

An overhead transport vehicle according to an example embodiment of the present invention is an overhead transport vehicle to transport a container while holding down a lid placed atop the container, the overhead transport vehicle including a holder to hold the container, and an elevation driver to raise and lower the holder, wherein the holder includes a lid presser to press the lid placed atop the container from above by a weight of the container when the container is held on the holder.

According to the overhead transport vehicle according to the above example embodiment, the lid of the container can be held down without using a driving motor, and it is thus possible, with a simple configuration, to transport the container while holding down the lid of the container.

In the overhead transport vehicle of the above example embodiment, the lid presser may include a first contact to press the lid placed atop the container from above, and a second contact to come into contact with a lower surface of a flange at an upper end of the container, when the holder is raised by the elevation driver, the second contact may come into contact with the lower surface of the flange and may be rotated around a shaft along a horizontal direction by a weight of the container, and the first contact may rotate around the shaft so as to follow the rotation of the second contact to press the lid from above. According to such a configuration, the first contact can press the lid by rotating so as to follow the rotation of the second contact. In other words, the overhead transport vehicle can transport the container with the lid held down, even in those cases where a driving motor for holding down the lid is not included.

In the overhead transport vehicle of the above example embodiment, the lid presser may include a support to support the flange from below, and when the holder is raised by the elevation driver, the second contact may rotate toward a lower surface of the flange, and then the flange may be supported on the support. According to such a configuration, it is possible to reliably support the flange.

In the overhead transport vehicle of the above example embodiment, the lid presser is configured to grip the container using the first contact and the support. According to such a configuration, it is possible to hold down the lid while gripping the container.

In the overhead transport vehicle of the above example embodiment, the lid presser is provided in a pair corresponding to both ends of the container. According to such a configuration, it is possible to stably hold the container and hold down the lid.

In the overhead transport vehicle of the above example embodiment, the first contact may include a first roller to press the lid from above, and the second contact may include a second roller to come into contact with the lower surface of the flange when the holder is raised by the elevation driver. According to such a configuration, it is possible to suppress friction occurring during the rotation of the first contact and the second contact.

In the overhead transport vehicle of the above example embodiment, the holder may include a holder main body to which the lid presser is attached, and a lid holder that is provided below the holder main body to hold the lid by suspending the lid using an elastic member, and the lid may be removably held on the lid holder. According to such a configuration, it is possible to transport various types of containers.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic configuration diagram of an overhead transport vehicle according to an example embodiment of the present invention.

FIG. 2 is a perspective view of a gripper according to an example embodiment of the present invention, seen from the rear side.

FIG. 3 is a perspective view of the gripper according to an example embodiment of the present invention, seen from the front side.

FIG. 4 is a configuration example of a lid presser according to an example embodiment of the present invention.

FIG. 5 is a diagram for describing the flow of operations in which the overhead transport vehicle an example embodiment of the present invention holds a container.

FIG. 6 is a diagram for describing the flow of operations in which the overhead transport vehicle an example embodiment of the present invention holds the container.

FIG. 7 is a diagram for describing the flow of operations in which the overhead transport vehicle an example embodiment of the present invention holds the container.

FIG. 8 is a diagram showing a state in which gripping is possible, an example embodiment of the present invention.

FIG. 9 is a diagram for describing the flow of operations in which the overhead transport vehicle an example embodiment of the present invention holds the container.

FIG. 10 is a perspective view showing how first rollers an example embodiment of the present invention press against the lid.

FIG. 11 is a diagram for describing the flow of operations in which the overhead transport vehicle an example embodiment of the present invention holds the container.

### DETAILED DESCRIPTION OF THE EXAMPLE EMBODIMENTS

Hereinafter, example embodiments of the present invention will be described. However, the following example embodiments do not limit the present invention according to the claims, and not all combinations of elements and features described in the example embodiments are essential. In the drawings, the same or similar elements or features are denoted by the same reference signs, and redundant descriptions may be omitted. The shapes and sizes of elements in the drawings may be exaggerated for clarity, and the dimensions and shapes may differ from the actual product.

In the drawings, an XYZ Cartesian coordinate system is used to describe directions in each drawing. In the XYZ Cartesian coordinate system, a plane that is parallel to a horizontal plane is defined as an XY plane. A direction along this XY plane is denoted as X direction, and a direction orthogonal to the X direction is denoted as Y direction. A direction perpendicular to the XY plane is denoted as Z direction. For each of the X direction, the Y direction, and the Z direction, description is made with a definition in which a direction indicated by an arrow is the positive (+) direction and a direction opposite to the direction indicated by the arrow is the negative (−) direction.

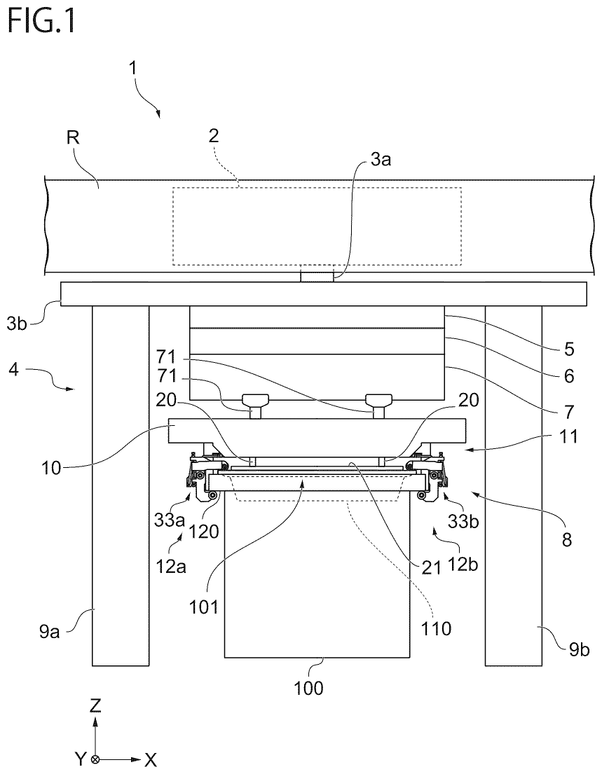

FIG. 1 is a schematic configuration diagram of an overhead transport vehicle 1 according to the present example embodiment. The overhead transport vehicle 1 is configured to travel along a track R, which is provided at a position higher than the floor surface, such as on a ceiling, and transports a container 100 in a suspended state. The container 100 may contain, for example, a liquid. The container 100 includes an opening 101 at its top. The overhead transport vehicle 1 is operable to place the lid 110 atop the container 100 so as to seal the opening 101. The container 100 includes a flange 120.

The flange 120 is at the upper end of the container 100. That is to say, the flange 120 may surround the opening 101. The overhead transport vehicle 1 is configured to transport the container 100 while holding down the lid 110 placed atop the container 100. It should be noted that the X direction in FIG. 1 represents the traveling direction of the overhead transport vehicle 1. The +X direction may be referred to as the right side, and the −X direction as the left side. The Z direction in FIG. 1 represents the vertical direction of the overhead transport vehicle 1. The Y direction in FIG. 1 represents the widthwise direction of the overhead transport vehicle 1.

The overhead transport vehicle 1 includes, for example, a traveling driver 2, a coupler 3a, a support 3b, and a main body 4.

The traveling driver 2 generates a driving force to cause the overhead transport vehicle 1 to travel. The traveling driver 2 includes, for example, wheels, a linear motor or a rotary motor, and a rotary encoder or a linear encoder. The wheels are arranged so as to be in contact with the track R, and are driven to rotate by the driving force of the traveling driver 2. The traveling driver 2 is configured or programmed to control the linear motor or the rotary motor on the basis of the detection results such as the rotation speed of the wheels detected by the rotary encoder or the linear encoder, and control the speed of stopping position of the overhead transport vehicle 1.

The coupler 3a couples the traveling driver 2 and the support 3b. For example, one end of the coupler 3a is connected to the traveling driver 2 and the other end to the support 3b. The support 3b is arranged along the horizontal plane and supports the main body 4.

The main body 4 is coupled to the traveling driver 2 via the coupler 3a and travels along the track R. The main body 4 includes a horizontal driver 5, a rotation driver 6, an elevation driver 7, a holder 8, a cover 9a, and a cover 9b.

The horizontal driver 5 is connected to the other end of the coupler 3a. The horizontal driver 5 causes the rotation driver 6, the elevation driver 7, and the holder 8 to move in the widthwise direction within a horizontal plane. The rotation driver 6 may include an electric motor or the like, and causes the elevation driver 7 and the holder 8 to rotate within a horizontal plane. The elevation driver 7 is controlled, for example, by a controller (not shown in the drawings) provided in the overhead transport vehicle 1, and lowers or raises the holder 8 at a predetermined speed and also maintains the holder 8 at a target height. The elevation driver 7 is, for example, a hoist. The elevation driver 7, for example, lowers the holder 8 by feeding out suspenders 71, such as wires and ropes and raises the holder 8 by winding up the suspenders 71.

The horizontal driver 5, the rotation driver 6, and the elevation driver 7 mentioned above are supported on the overhead transport vehicle 1, and move together with the overhead transport vehicle 1 in the traveling direction. The cover 9a is provided on the −X side of the horizontal driver 5, the rotation driver 6, and the elevation driver 7, and the cover 9b is provided on the +X side. The cover 9a and the cover 9b are each fixed to the support 3b and arranged so as to extend from the support 3b in the −Z direction.

The holder 8 places the lid 110 atop the container 100. The holder 8 holds the container 100 while holding down the lid 110 placed atop the container 100 so that the lid 110 does not come off. The holder 8 includes, for example, a holder main body 10, a lid holder 11, and two grippers 12 (grippers 12a, 12b). The holder 8 uses the two grippers 12a, 12b to grip the container 100 on which the lid 110 is placed.

The holder main body 10 is connected to the suspenders 71. The holder main body 10 is suspended from the elevation driver 7 via the suspenders 71, and is raised or lowered by the elevation driver 7. The holder main body 10 supports the two grippers 12a, 12b. Specifically, the gripper 12a is supported on the −X side of the holder main body 10, and the gripper 12b is supported on the +X side of the holder main body 10.

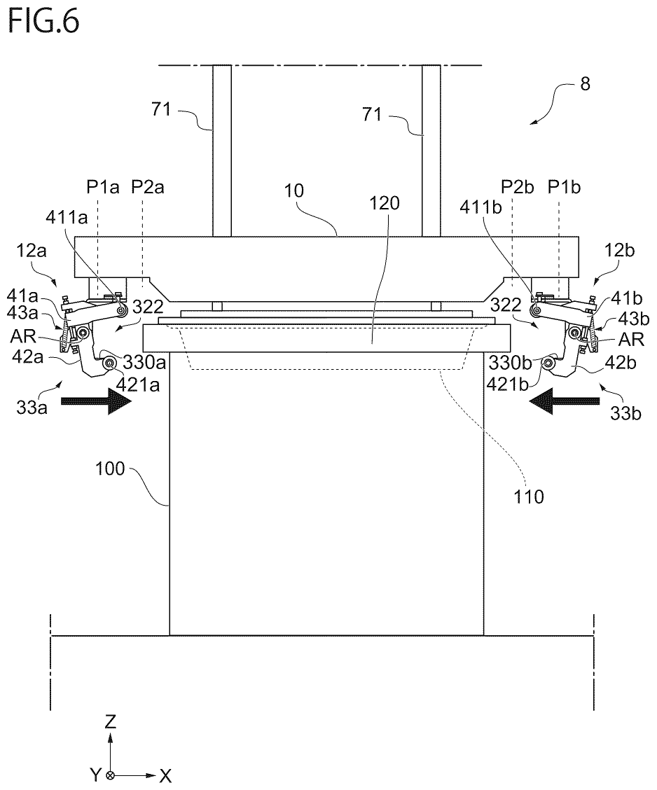

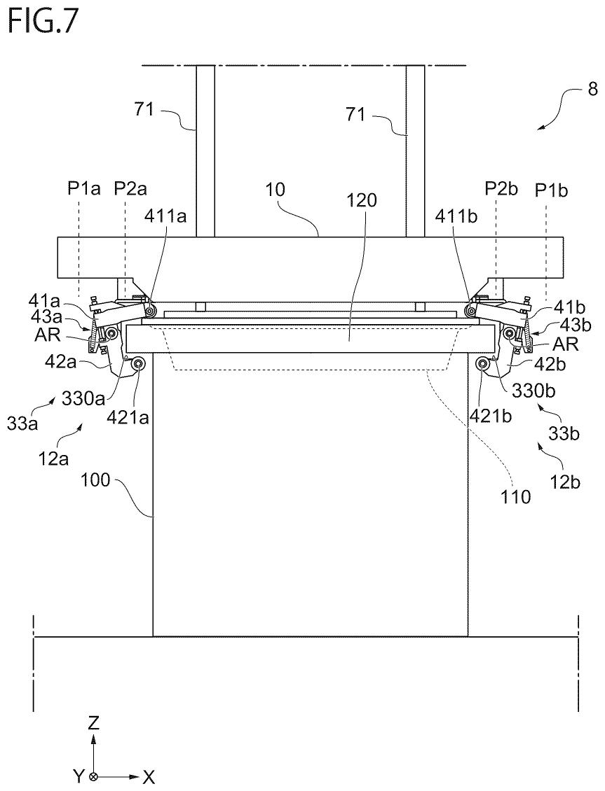

The holder main body 10 can move the grippers 12a, 12b in the traveling direction. Specifically, when gripping the container 100, the holder main body 10 moves the grippers 12a, 12b to the inner side of the holder 8, that is, to the container 100 side. In other words, when gripping the container 100, the holder main body 10 moves the gripper 12a a predetermined distance in the +X direction, moving it from a first position P1a (for example, see FIG. 6) to a second position P2a (for example, see FIG. 7), and moves the gripper 12b a predetermined distance in the −X direction, moving it from a first position P1b to a second position P2b.

When the grip on the container 100 is released, the holder main body 10 moves the grippers 12a, 12b to the outer side of the holder 8 (in the direction opposite to the container 100 side). In other words, when the grip on the container 100 is released, the holder main body 10 moves the gripper 12a the predetermined distance in the −X direction and moves the gripper 12b the predetermined distance in the +X direction. The holder main body 10 has, for example, guide rails that allow the grippers 12a, 12b to move in the traveling direction.

The lid holder 11 is arranged below the holder main body 10 and holds the lid 110 in the horizontal direction. The lid 110 is removably held on the lid holder 11. The lid holder 11 includes, for example, four elastic members 20 and a support plate 21.

Each of the four elastic members 20 has one end fixed to the holder main body 10 and the other end fixed to the support plate 21. The four elastic members 20 preferably all have the same length, for example. The support plate 21 is, for example, a plate-shaped structure to which the lid 110 is attached. For example, the other ends of the four elastic members 20 are each fixed at positions near the four corners of the upper surface of the support plate 21. In other words, between the positions near the four corners of the upper surface of the support plate 21 and the holder main body 10, the four elastic members 20 are arranged so as to extend in the +Z direction.

The lid 110 is removably held on the lower surface of the support plate 21. For example, the lid 110 is attached to the lower surface of the support plate 21 using bolts or the like. Thus, the holder main body 10 holds the lid 110 below the holder main body 10 by suspending the lid 110 by the elastic members 20. The elastic members 20 are, for example, springs.

The gripper 12a and the gripper 12b preferably have the same basic configuration, for example. For the purpose of distinguishing the components of the gripper 12a from those of the gripper 12b, a suffix “a” may be appended to the end of the reference signs for the components of the gripper 12a, and a suffix “b” to those of the components of the gripper 12b when described. When no distinction is made between the gripper 12a and the gripper 12b, they may collectively be referred to as “gripper 12”.

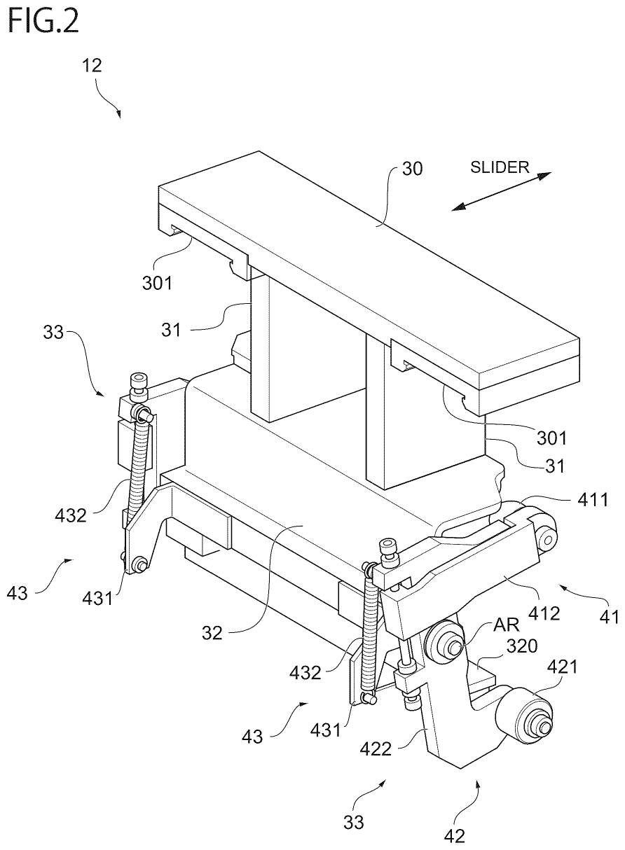

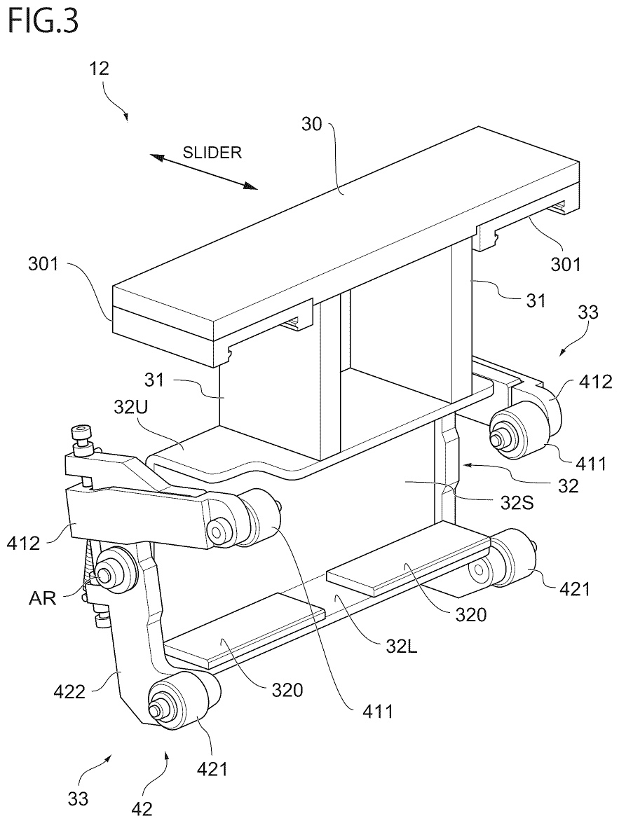

FIG. 2 is a perspective view of the gripper 12 according to the present example embodiment, seen from the rear side. FIG. 3 is a perspective view of the gripper 12 according to the present example embodiment, seen from the front side. The gripper 12 includes a slider 30, a coupler 31, a base 32, and lid pressers 33. The slider 30 is attached to the holder main body 10 so as to be slidable in the ±X directions. The slider 30 is, for example, a plate-shaped structure arranged such that its lengthwise direction extends along the Y direction. The slider 30 includes channels 301 in the lower surface thereof. The slider 30 is slidably provided to move in the ±X directions, with its channels 301 fitted on the guide rails provided on the holder main body 10.

The coupler 31 connects the slider 30 and an upper portion 32U of the base 32. The coupler 31 is arranged along the vertical direction, with one end fixed to the slider 30 and the other end fixed to the base 32.

For example, the base 32 preferably is substantially channel-shaped (substantially U-shaped or substantially C-shaped), where, when viewed in a plan view from the Y-direction, its opening is positioned on the side of the container 100, which is held by the holder 8. In the base 32, the upper portion 32U, a side portion 32S, and a lower portion 32L define a substantially channel-shape, and a support 320 to support the flange 120 from below is located on the upper surface of the lower portion 32L.

On the base 32, one or more lid pressers 33 are provided so as to be rotatable around a shaft along the Y direction. As an example, in the example shown in FIG. 2, two lid pressers 33 are provided on the base 32 so as to be each rotatable around a shaft along the Y direction. For example, the lid pressers 33 are provided on both ends of the base 32 in the Y direction. Of the lid pressers 33 provided on both ends of the base 32 in the Y direction, one may be referred to as lid presser 33a and the other as lid presser 33b. A rotation shaft AR along the Y direction is fixed to the side portion 32S of the lid presser 33. The lid presser 33 is supported on the rotation shaft AR so as to be rotatable along the circumferential surface of the rotation shaft AR, with the rotation shaft AR serving as the center of rotation.

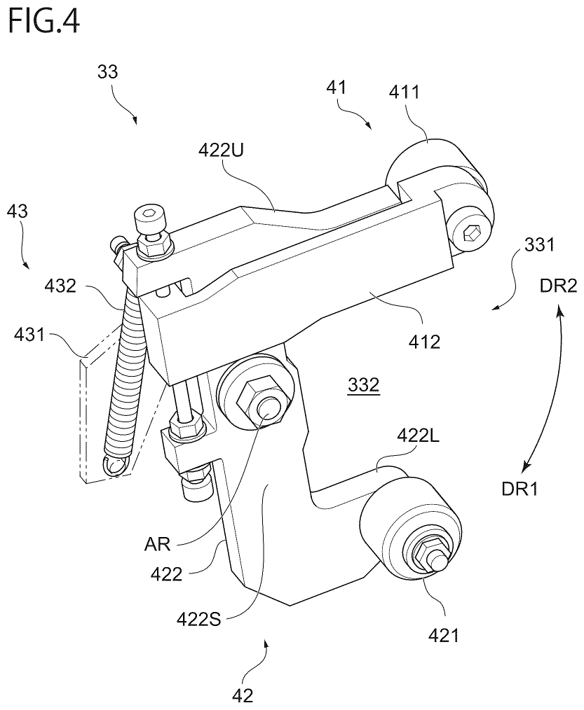

FIG. 4 is a configuration example of the lid presser 33 according to the present example embodiment. The lid presser 33 presses the lid 110 placed atop the container 100 downward (in the −Z direction). Specifically, when the container 100 is held by the holder 8, the lid presser 33 presses the lid 110 downward from above by the weight of the container 100 itself. A configuration example of the lid presser 33 will be described below.

The lid presser 33 preferably is substantially channel-shaped (substantially U-shaped or substantially C-shaped) in a plan view from the −Y direction, with an opening 331 located on the inner side of the holder 8 (the side where the container 100 is accommodated). The lid presser 33 includes, for example, a first contact 41, a second contact 42, and a biaser 43.

The first contact 41 is a structure to press the lid 110 placed atop the container 100 from above. The first contact 41 is fixed on the second contact 42. The first contact 41 includes, for example, a roller 411 (first roller) and a roller support 412.

The roller 411 comes into contact with an upper portion of the lid 110. When the container 100 is held by the holder 8, the roller 411 comes into contact with the upper portion of the lid 110 and press it downward. The roller support 412 supports the roller 411. For example, the roller support 412 has the roller 411 mounted at its distal end.

The second contact 42 includes, for example, a roller 421 (second roller) and a roller support 422. When the container 100 is held by the holder 8, the roller 421 comes into contact with the lower surface of the flange 120. The roller support 422 supports the roller 421. The roller support 412 is fixed on the roller support 422 by screws, bolts or the like. The roller support 422 is supported on the rotation shaft AR so as to be rotatable along the circumferential surface of the rotation shaft AR, with the rotation shaft AR serving as the center of rotation.

The roller support 422 includes a distal end, and has the roller 421 mounted at the distal end. In the present example embodiment, the roller support 422 preferably is substantially channel-shaped (substantially U-shaped or substantially C-shaped) with the opening 331 located on the inner side of the holder 8 in a plan view from the −Y direction. In the roller support 422, an upper portion 422U, a side portion 422S, and a lower portion 422L form the channel-shape of the roller support 422, and the roller support 412 is fixed along the upper portion 422U. The side portion 422S is supported on the rotation shaft AR. The lower portion 422L corresponds to the distal end of the roller support 422.

The biaser 43 biases the lid presser 33 towards a predetermined attitude. The predetermined attitude refers, for example, to a state in which the opening 331 of the lid presser 33 faces inward (the side where the container 100 is accommodated) and obliquely upward in a plan view from the −Y direction. The biaser 43 includes a fixing member 431 and an elastic member 432. The fixing member 431 fixes, for example, one end of the elastic member 432 to the side portion 32S. The other end of the elastic member 432 is fixed to the side portion 422S. When the lid presser 33 rotates in a first direction DR1 along the rotation shaft AR, the biaser 43 biases the lid presser 33 to rotate in a second direction DR2, which is opposite to the first direction DR1, along the rotation shaft AR by the biasing force of the elastic member 432. When the overhead transport vehicle 1 is viewed from the −Y direction as shown in FIG. 1, in the lid presser 33a, the first direction DR1 is clockwise and the second direction DR2 is counterclockwise. When the overhead transport vehicle 1 is viewed from the −Y direction as shown in FIG. 1, in the lid presser 33b, the first direction DR1 is counterclockwise and the second direction DR2 is clockwise.

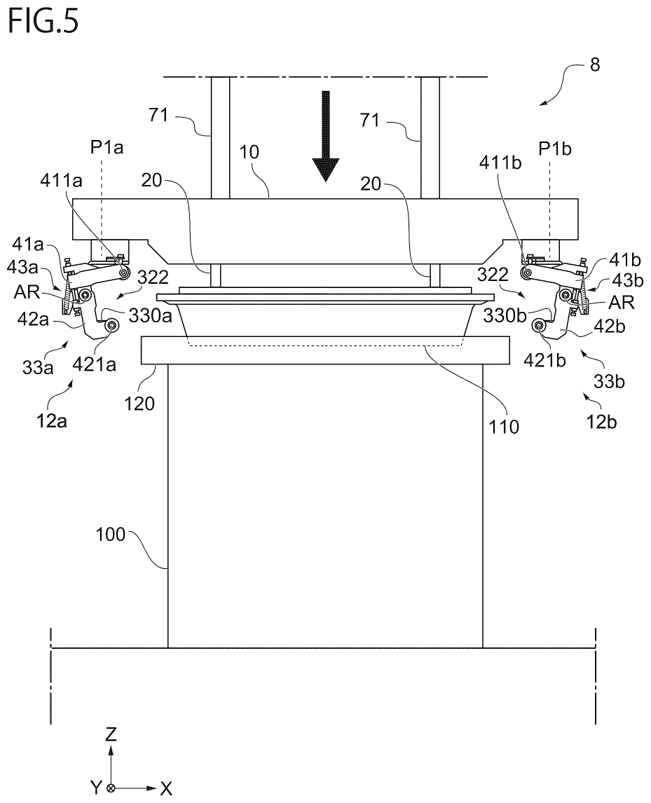

Next, the flow of operations performed by the overhead transport vehicle 1 to hold the container 100 will be described with reference to FIG. 5 through FIG. 11. First, the overhead transport vehicle 1 travels along the track R and stops at a predetermined position on the track R. At this time, the overhead transport vehicle 1 is holding the lid 110, intended for placement onto the container 100, by the lid holder 11, however, it is not holding the container 100. When the overhead transport vehicle 1 is not holding the container 100, both the lid presser 33a and the lid presser 33b are maintained in a predetermined attitude by the biaser 43, as shown in FIG. 5. In other words, in a plan view from the −Y direction, the lid presser 33a is maintained in a state in which the opening 331 of the lid presser 33 is oriented diagonally upward to the right. On the other hand, in a plan view from the −Y direction, the lid presser 33b is maintained in a state in which the opening 331 of the lid presser 33 is oriented diagonally upward to the left. When the overhead transport vehicle 1 is not holding the container 100, the gripper 12a is positioned at the first position Pla, and the gripper 12b is positioned at the first position P1b.

As shown in FIG. 5, as the overhead transport vehicle 1 uses the elevation driver 7 to lower the holder 8 at the predetermined position on the track R, the lid 110 gradually approaches the container 100. When the overhead transport vehicle 1 has lowered the holder 8 to a prescribed position by the elevation driver 7, the lid 110 comes in close contact with the container 100 and the lid 110 is placed on the container 100.

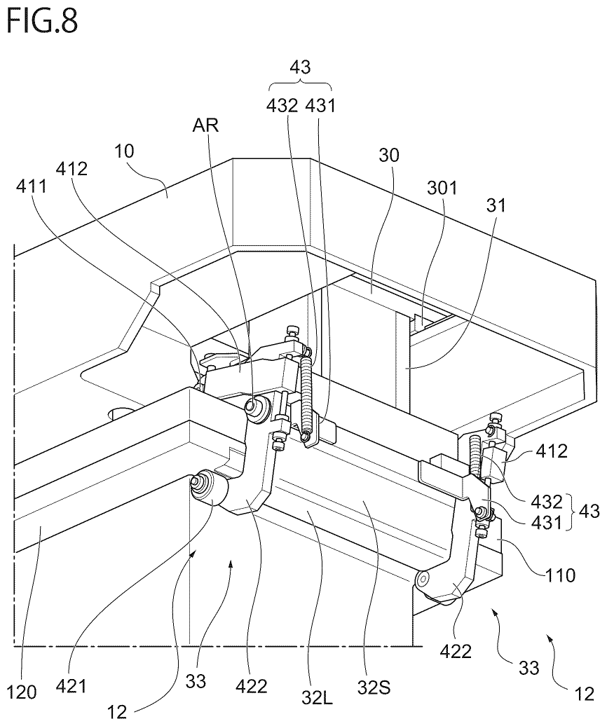

Once the lid 110 is placed on the container 100, the overhead transport vehicle 1, as shown in FIG. 6, moves the gripper 12a a predetermined distance in the +X direction, moving it from the first position P1a to the second position P2a, and moves the gripper 12b a predetermined distance in the −X direction, moving it from the first position P1b to the second position P2b. As a result, the gripper 12a and the gripper 12b are brought into a state where they can grip the container 100 (hereinafter, referred to as “grippable state”). FIG. 7 is a diagram showing the grippable state in a plan view from the −Y direction. FIG. 8 is a perspective view showing the gripper 12 in the grippable state. In the grippable state, the flange 120 is positioned in a region 332 on the inner side of the gripper 12. In other words, in the grippable state, the roller 411 is arranged directly above the vicinity of the edge of the lid 110 and the roller 421 is arranged directly below the flange 120.

Once the holder 8 of the overhead transport vehicle 1 is in the grippable state, the elevation driver 7 gradually raises the holder 8. When the operation of raising the holder 8 is performed, the holder main body 10 first ascends, and in response to the ascending motion of the holder main body 10, the grippers 12a, 12b, which are mounted on the left and right sides of the holder main body 10, also ascend.

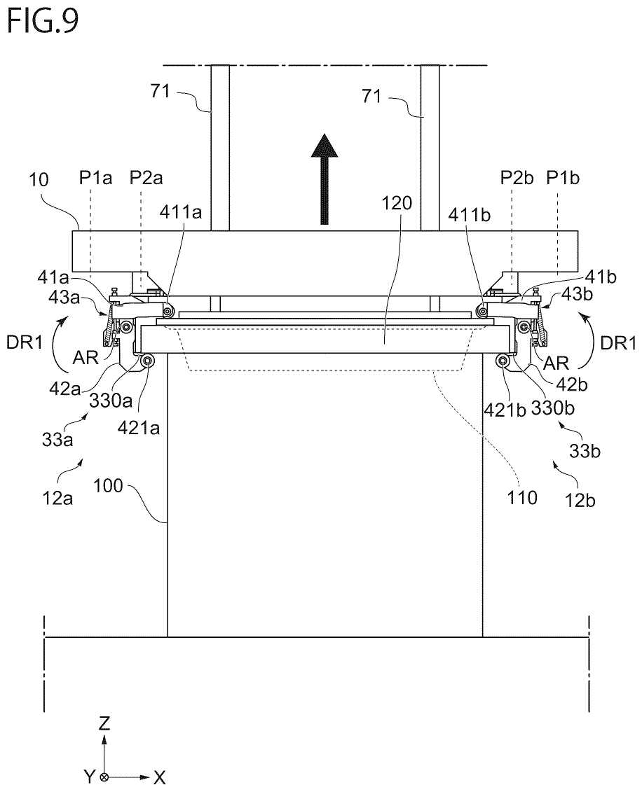

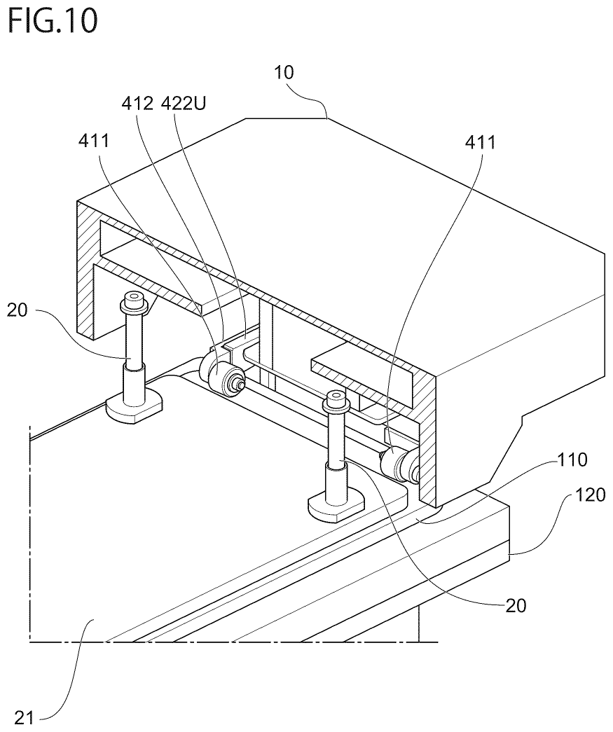

As the gripper 12 ascends, and as exemplified in FIG. 9, the first contact 41 rotates around the rotation shaft AR, following the rotation of the second contact 42, which is driven by the weight of the container 100 itself. Consequently, the roller 411 presses the lid 110 from above. As a result, the gripper 12 grips the container 100 while holding down the lid 110. FIG. 9 is a diagram showing a state in which the grippers 12 is gripping the container 100. FIG. 10 is a perspective view showing how the rollers 411 according to the present example embodiment press against the lid 110.

Specifically, as the gripper 12a ascends, the roller 421a comes into contact with the lower surface of the flange 120, and the weight of the container 100 presses the roller 421a downward. As a result, the second contact 42a rotates clockwise along the rotation shaft AR. When the second contact 42a rotates clockwise along the rotation shaft AR, the lower portion of the flange 120 is supported on the support 320a. In other words, after the second contact 42a has rotated clockwise along the rotation shaft AR, the flange 120 is placed on the support 320a. For example, in the case where the lid presser 33a is in a predetermined attitude, the upper surface of the roller 421a is arranged at a position higher than the placement surface of the support 320a. Therefore, after the roller 421a has come into contact with the lower portion of the flange 120, the flange 120 is placed on the placement surface of the support 320a.

The first contact 41a is fixed on the second contact 42a. Therefore, the first contact 41a rotates clockwise around the rotation shaft AR so as to follow the rotation of the second contact 42a to press the lid 110 with the roller 411a from above. As a result, the gripper 12a grips the container 100 using the first contact 41a and the support 320a while holding down the lid 110 placed atop the container 100 with the first contact 41a.

Similarly, as the gripper 12b ascends, the roller 421b comes into contact with the lower surface of the flange 120, and the weight of the container 100 presses the roller 421b downward. As a result, the second contact 42b rotates counterclockwise along the rotation shaft AR. When the second contact 42b rotates counterclockwise along the rotation shaft AR, the lower portion of the flange 120 is supported on the support 320b. In other words, after the second contact 42b has rotated counterclockwise along the rotation shaft AR, the flange 120 is placed on the support 320b. For example, when the lid presser 33b is in a predetermined attitude, the upper surface of the roller 421b is arranged at a position higher than the placement surface of the support 320b. Therefore, after the roller 421b has come into contact with the lower portion of the flange 120, the flange 120 is placed on the placement surface of the support 320b.

The first contact 41b is fixed on the second contact 42b. Therefore, the first contact 41b rotates counterclockwise around the rotation shaft AR so as to follow the rotation of the second contact 42b to press the lid 110 with the roller 411b from above. As a result, the gripper 12b grips the container 100 using the first contact 41b and the support 320b while holding down the lid 110 placed atop the container 100 with the first contact 41b.

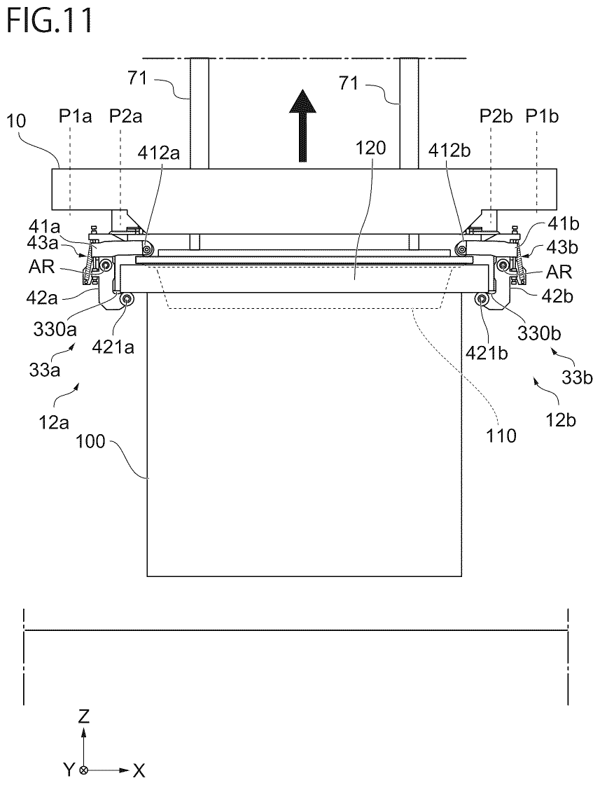

Even after the container 100 is gripped by the gripper 12a, 12b, the elevation driver 7 continues to perform the operation of raising the holder 8. Once the operation of gripping the container 100 performed by the grippers 12a, 12b is complete, the container 100 is raised as exemplified in FIG. 11. The container 100, with the lid 110 held down, is then accommodated within an accommodating space between the cover 9a and the cover 9b. The overhead transport vehicle 1 then transports the container 100 to a target location while holding down the lid 110 placed atop the container 100.

Thus, the overhead transport vehicle 1 according to the present example embodiment can hold down the lid 110 without using a driving motor. It is therefore possible, with a simple configuration, to transport the container 100 while holding down the lid 110 of the container 100.

In the overhead transport vehicle 1 described above, an example has been described in which the lid presser 33 presses the lid 110 placed atop the container 100 to push a portion of the lid 110 into the container 100. However, the present invention is not limited to this example. For example, it is sufficient if a portion of the lid 110 is not pushed into the container 100 but is simply pressed against the flange 120. In other words, in the present example embodiment, any configuration is acceptable as long as the lid presser 33 presses the lid 110 placed atop the container 100 in a way that prevents the lid 110 from coming off. The lid 110 may include a portion pushed into the container 100, or it may simply be pressed against the flange 120 without any portion or the entirety being pushed into the container 100.

Example embodiments of the present invention may have any of the following configurations.

### Configuration 1

An overhead transport vehicle 1 to transport a container 100 while holding down a lid 110 placed atop the container 100, the overhead transport vehicle 1 including a holder 8 to hold the container 100, and an elevation driver 7 to raise and lower the holder 8, wherein the holder 8 includes a lid presser 33 to press the lid 110 placed atop the container 100 from above by a weight of the container 100 when the container 100 is held on the holder 8.

### Configuration 2

The overhead transport vehicle 1 according to configuration 1, wherein the lid presser 33 includes a first contact 41 to press the lid 110 placed atop the container 100 from above, and a second contact 42 to come into contact with a lower surface of a flange 120 at an upper end of the container 100, and when the holder 8 is raised by the elevation driver 7, the second contact 42 is movable into contact with the lower surface of the flange 120 and is rotatable around a shaft along a horizontal direction by a weight of the container 100, and the first contact 41 is rotatable around the shaft so as to follow the rotation of the second contact 42 to press the lid 110 from above.

### Configuration 3

The overhead transport vehicle 1 according to configuration 1 or 2, wherein the lid presser 33 includes a support 320 to support the flange 120 from below, and when the holder 8 is raised by the elevation driver 7, the second contact 42 is rotatable toward the lower surface of the flange 120 resulting in the flange 120 being supported on the support 320.

### Configuration 4

The overhead transport vehicle 1 according to any one of configurations 1 to 3, wherein the lid presser 33 is configured to grip the container 100 using the first contact 41 and the support while holding down the lid 110 placed atop the container 100 with the first contact 41.

### Configuration 5

The overhead transport vehicle 1 according to any one of configurations 1 to 4, wherein the lid presser 33 is provided in a pair corresponding to both ends of the container 100.

### Configuration 6

The overhead transport vehicle according to configuration 2, wherein the first contact 41 includes a first roller to press the lid 110 from above, and the second contact 42 includes a second roller to come into contact with the lower surface of the flange 120 when the holder 8 is raised by the elevation driver 7.

### Configuration 7

The overhead transport vehicle 1 according to any one of configurations 1 to 6, wherein the holder 8 includes a holder main body 10 to which the lid presser 33 is attached, and a lid holder 11 that is provided below the holder main body 10 to hold the lid 110 by suspending the lid 110 using an elastic member 20, and the lid 110 is removably held on the lid holder 11.

One or more of the elements or features described in the above example embodiments may be omitted in some cases. Furthermore, one or more of the elements or features described in the above example embodiments may be combined where appropriate. The order of executing procedures in the example embodiments can be implemented in an arbitrary order unless the result of the previous procedure is used in the following procedure. While operations in the above example embodiments have been described with expressions such as “first”, “next”, and “subsequently” for the sake of convenience, the operations need not always be implemented in that order.

The contents of Japanese Patent Application No. 2023-072521 and all documents cited in the detailed description of example embodiments of the present invention are incorporated herein by reference to the extent permitted by law.

While example embodiments of the present invention have been described above, it is to be understood that variations and modifications will be apparent to those skilled in the art without departing from the scope and spirit of the present invention. The scope of the present invention, therefore, is to be determined solely by the following claims.

1-7. (canceled)

8: An overhead transport vehicle to transport a container while holding down a lid placed atop the container, the overhead transport vehicle comprising:
a holder to hold the container; and
an elevation driver to raise and lower the holder; wherein
the holder includes a lid presser to press the lid placed atop the container from above by a weight of the container when the container is held on the holder.

9: The overhead transport vehicle according to claim 8, wherein
the lid presser includes a first contact to press the lid placed atop the container from above; and
a second contact to come into contact with a lower surface of a flange at an upper end of the container; wherein
when the holder is raised by the elevation driver, the second contact is movable to contact with the lower surface of the flange and is rotatable around a shaft along a horizontal direction by a weight of the container; and
the first contact is rotatable around the shaft so as to follow the rotation of the second contact to press the lid from above.

10: The overhead transport vehicle according to claim 9, wherein the lid presser includes a support to support the flange from below; and
when the holder is raised by the elevation driver, the second contact is rotatable toward a lower surface of the flange resulting in the flange being supported on the support.

11: The overhead transport vehicle according to claim 10, wherein the lid presser is configured to grip the container using the first contact and the support while holding down the lid placed atop the container with the first contact.

12: The overhead transport vehicle according to claim 8, wherein the lid presser is provided in a pair corresponding to both ends of the container.

13: The overhead transport vehicle according to claim 9, wherein
the first contact includes a first roller to press the lid from above; and
the second contact includes a second roller to come into contact with the lower surface of the flange when the holder is raised by the elevation driver.

14: The overhead transport vehicle according to claim 8, wherein
the holder includes a holder main body to which the lid presser is attached, and a lid holder that is provided below the holder main body to hold the lid by suspending the lid using an elastic member; and
the lid is removably held on the lid holder.
